(19) United States
(12) Patent Application Publication
(10) Pub. No.: US 2011/0310514 A1
(43) Pub. Date: Dec. 22, 2011

(54) Electrostatic discharge protection circuit

(76) Inventors: Shao-Chang Huang, Hsinchu City (TW); Wei-Yao Lin, Hsinchu County (TW); Tang-Lung Lee, Taipei County (TW); Kun-Wei Chang, Taipei County (TW); Chiun-Chi Shen, Hsin-Chu Hsien (TW)

(21) Appl. No.: 12/817,215

(22) Filed: Jun. 17, 2010

(51) Int. Cl. H02H 9/04; H01L 27/06

(52) U.S. Cl. 361/56; 257/355; 257/E27.016

(57) ABSTRACT

An electrostatic discharge (ESD) protection circuit is coupled between a first terminal and a second terminal of an integrated circuit. The integrated circuit receives an input signal through the first terminal. The second terminal is coupled to a voltage source. The ESD protection circuit includes a PMOS transistor and a deep N-well NMOS transistor. When the static electricity is inputted to the first terminal, the static electricity flows to the voltage source through the corresponding parasitic diode and the corresponding parasitic bipolar transistor of the PMOS transistor and the deep N-well NMOS transistor. In addition, the input signal is not affected by the ESD protection circuit because the parasitic diodes of the PMOS transistor and the deep N-well NMOS transistor are reversely connected. Thus, the ESD protection circuit prevents the integrated circuit from being damaged by the static electricity and increases the operation voltage range of the input signal.

### BACKGROUND OF THE INVENTION

1. Field of the Invention

The present invention is related to an electrostatic discharge (ESD) protection circuit for increasing the operation voltage range of a signal inputted into an integrated circuit.

2. Description of the Prior Art

Please refer to FIG. 1. FIG. 1 is a diagram illustrating a conventional ESD protection circuit 100. The ESD protection circuit 100 is coupled to terminals T₁, T₂, and T₃ of an integrated circuit 101 for preventing the integrated circuit 101 from being damaged by the static electricity. The integrated circuit 101 receives an input signal S_{IN} through the terminal T₁; the terminal T₂ is coupled to a voltage source V_{DD} (for example, 3.3V); and the terminal T₃ is coupled to a voltage source V_{SS} (for example, 0V). The ESD protection circuit 100 includes a P-channel Metal Oxide Semiconductor (PMOS) transistor Q_{P1} and an N-channel Metal Oxide Semiconductor (NMOS) transistor Q_{N1}. The PMOS transistor Q_{P1} includes a drain (D), a gate (G), a source (S), and an N-well (W), wherein the source, the gate, and the N-well of the PMOS transistor Q_{P1} are all coupled to the terminal T₂, and the drain of the PMOS transistor Q_{P1} is coupled to the terminal T₁. The NMOS transistor Q_{N1} includes a drain (D), a gate (G), a source (S), and a P-well (W), wherein the source, the gate, and the P-well of the NMOS transistor Q_{N1} are all coupled to the terminal T₃, and the drain of the NMOS transistor Q_{N1} is coupled to the terminal T₁. In this way, the parasitic diode D_{QP1} of the PMOS transistor Q_{P1} is coupled between the terminals T₁ and T₂, and the parasitic diode D_{QN1} of the NMOS transistor Q_{N1} is coupled between the terminals T₁ and T₃, as shown in FIG. 1. Therefore, when the positive static electricity is generated from the input end END_{IN}, the parasitic diode D_{QP1} is turned on so that the ESD circuit 100 can dissipate the positive static electricity since the positive static electricity flows to the voltage source V_{DD} through the turned-on parasitic diode D_{QP1}. When the negative static electricity is generated from the input end END_{IN}, the parasitic diode D_{QN1} is turned on so that the ESD circuit 100 can dissipate the negative static electricity since the positive charges from the voltage source V_{SS} flow through the turned-on parasitic diode D_{QN1} to eliminate the negative static electricity.

However, when the voltage level of the input signal S_{IN} is higher than the sum of the voltage level of the voltage V_{DD} (3.3) and the forward voltage V_{FW} (about 0.7V) of the parasitic diode D_{QP1}, the parasitic diode D_{QP1} is turned on. Meanwhile, the input signal S_{IN} is dissipated by the voltage source V_{DD}, and a leakage current I_{L1} is generated between the input end END_{IN} and the voltage source V_{DD}. Similarly, when the voltage level of the input signal S_{IN} is lower than the voltage level of the voltage V_{SS} (0V) deducting the forward voltage V_{FW} (about 0.7V) of the parasitic diode D_{QN1}, the parasitic diode D_{QN1} is turned on. Meanwhile, the input signal S_{IN} is dissipated by the voltage source V_{SS} and a leakage current I_{L2} is generated between the input end END_{IN} and the voltage source V_{SS}. In other words, the operation voltage range of the input signal S_{IN} of the integrated circuit 101 is limited to be from (V_{SS}−V_{FW}) to (V_{DD}+V_{FW}) by the conventional ESD protection circuit 100. In addition, when the voltage level of the input signal S_{IN} is not within the operation voltage range, the leakage current is generated.

### SUMMARY OF THE INVENTION

The present invention provides an electrostatic discharge (ESD) protection circuit. The ESD protection circuit is coupled between a first terminal and a second terminal of an integrated circuit for preventing the integrated circuit from being damaged by static electricity. The ESD protection circuit comprises a first P-channel Metal Oxide Semiconductor (PMOS) transistor and a deep N-well N-channel Metal Oxide Semiconductor (NMOS) transistor. The first PMOS transistor comprises a source, a drain, a gate, and an N-well. The source of the first PMOS transistor is coupled to the first terminal. The gate of the first PMOS transistor is coupled to the drain of the first PMOS transistor. The N-well of the first PMOS transistor is coupled to the drain of the first PMOS transistor. The deep N-well NMOS transistor comprises a source, a drain, a gate, a P-well, and a deep N-well. The source of the deep N-well NMOS transistor is coupled to the second terminal. The drain of the deep N-well NMOS transistor is coupled to the drain of the first PMOS transistor. The gate of the deep N-well NMOS transistor is coupled to the second terminal. The P-well of the deep N-well NMOS transistor is coupled to the source of the deep N-well NMOS transistor. The deep N-well of the deep N-well NMOS transistor is utilized for covering the P-well of the deep N-well NMOS transistor. The deep N-well of the deep N-well NMOS transistor is coupled to a second voltage source.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional ESD protection circuit.

FIG. 2 is a diagram illustrating an ESD protection circuit according to a first embodiment of the present invention.

FIG. 3 is a cross section diagram of the ESD protection circuit of FIG. 2.

FIG. 4 and FIG. 5 are diagrams illustrating the operation principle of the ESD protection circuit dissipating the static electricity.

FIG. 6 and FIG. 7 are diagrams illustrating that the ESD protection circuit increases the operation voltage range of the input signal of the integrated circuit.

FIG. 8 is an ESD protection circuit according to a second embodiment of the present invention.

FIG. 9 is an ESD protection circuit according to a third embodiment of the present invention.

FIG. 10 is an ESD protection circuit according to a fourth embodiment of the present invention.

FIG. 11 is an ESD protection circuit according to a fifth embodiment of the present invention.

FIG. 12 is an ESD protection circuit according to a sixth embodiment of the present invention.

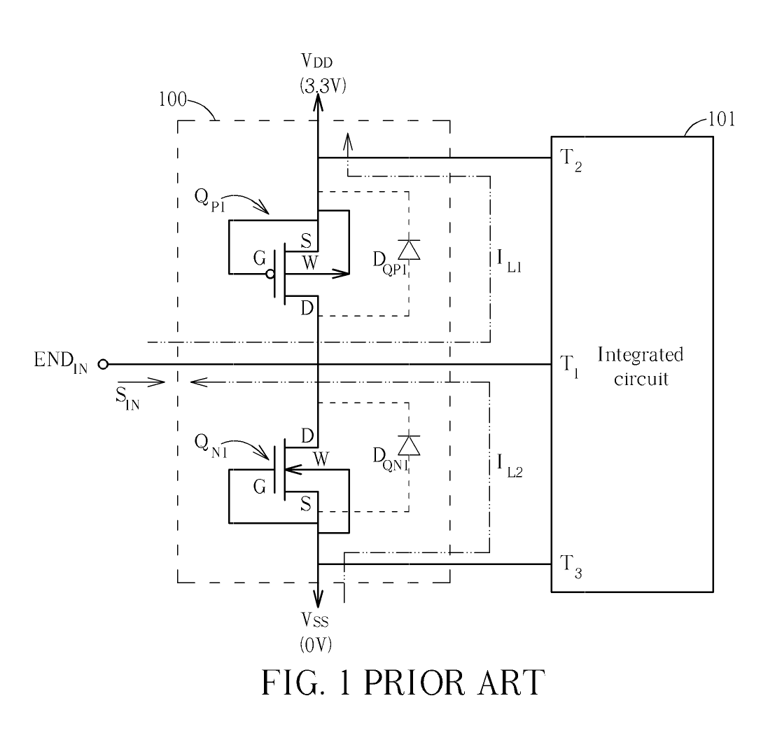

### DETAILED DESCRIPTION

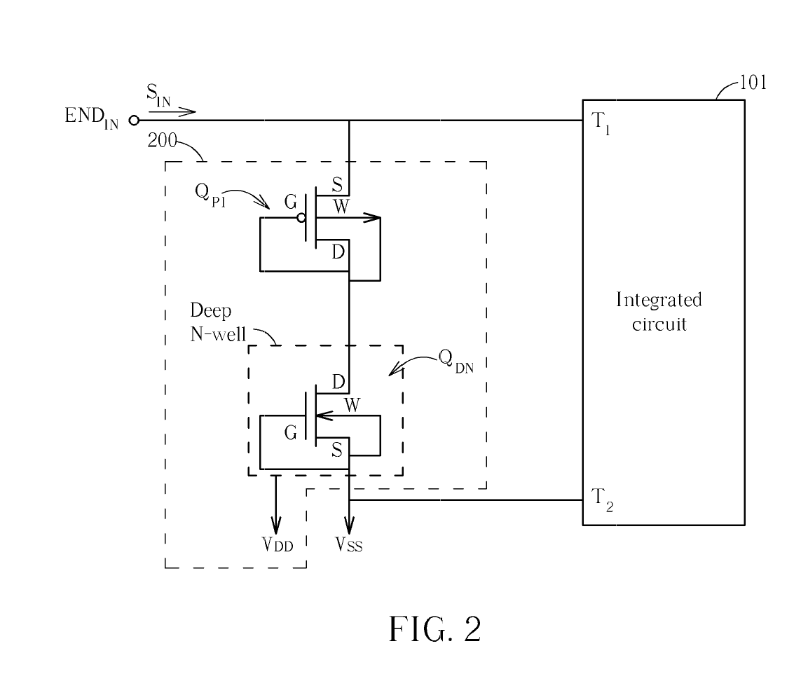

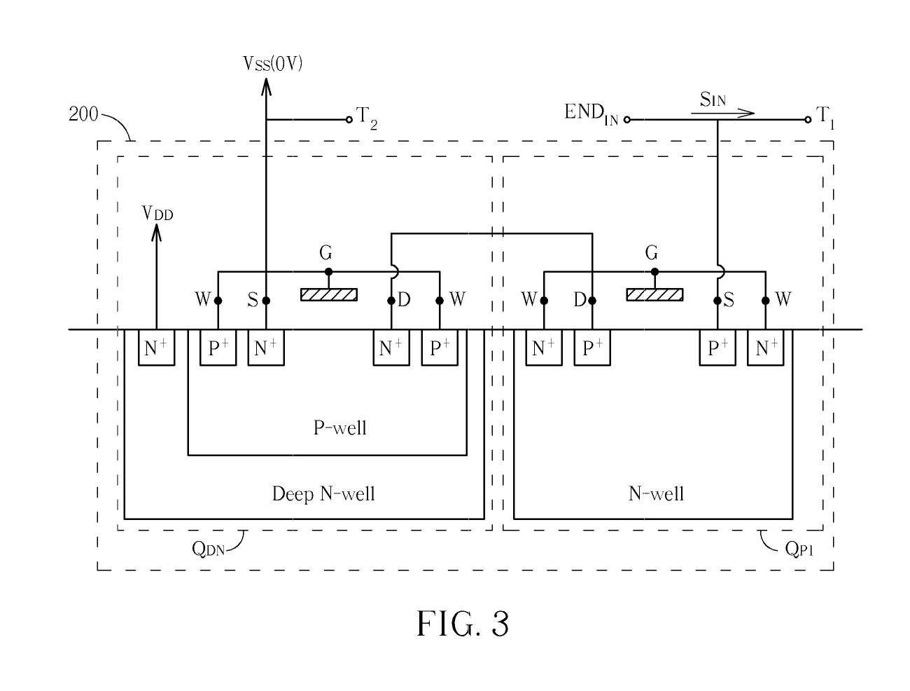

Please refer to FIG. 2 and FIG. 3. FIG. 2 is a diagram illustrating an ESD protection circuit 200 according to a first embodiment of the present invention. FIG. 3 is a cross section diagram of the ESD protection circuit 200. In FIG. 3, N+ represents n-type doping, and P+ represents p-type doping. In FIG. 2, the ESD protection circuit 200 is coupled between the terminals T₁ and T₂ of the integrated circuit 101 for preventing the integrated circuit 101 from being damaged by the static electricity. The terminal T₁ is utilized for the integrated circuit 101 to receive the input signal S_{IN} and the terminal T₂ is coupled to the voltage source V_{SS}. The ESD protection circuit 200 includes a PMOS transistor Q_{P1}, and a deep N-well NMOS transistor Q_{DN}. The PMOS transistor Q_{P1} includes a drain (D), a gate (G), a source (S), and an N-well (W), wherein the source of the PMOS transistor Q_{P1} is coupled to the terminal T₁, and the gate, the drain, and the N-well of the PMOS transistor Q_{P1} are all coupled to the deep N-well NMOS transistor Q_{DN}. The deep N-well NMOS transistor Q_{DN} includes a drain (D), a gate (G), a source (S), a P-well (W), and a deep N-well. The drain of the deep N-well NMOS transistor Q_{DN} is coupled to the drain of the PMOS transistor Q_{P1}. The P-well of the deep N-well NMOS transistor Q_{DN} is coupled to the source of the deep N-well NMOS transistor Q_{DN}. The gate, and the source of the deep N-well NMOS transistor Q_{DN} are both coupled to the terminal T₂. The deep N-well covers the P-well (as shown in FIG. 3), and is coupled to a voltage source (for example, V_{DD}) which provides a high-level voltage.

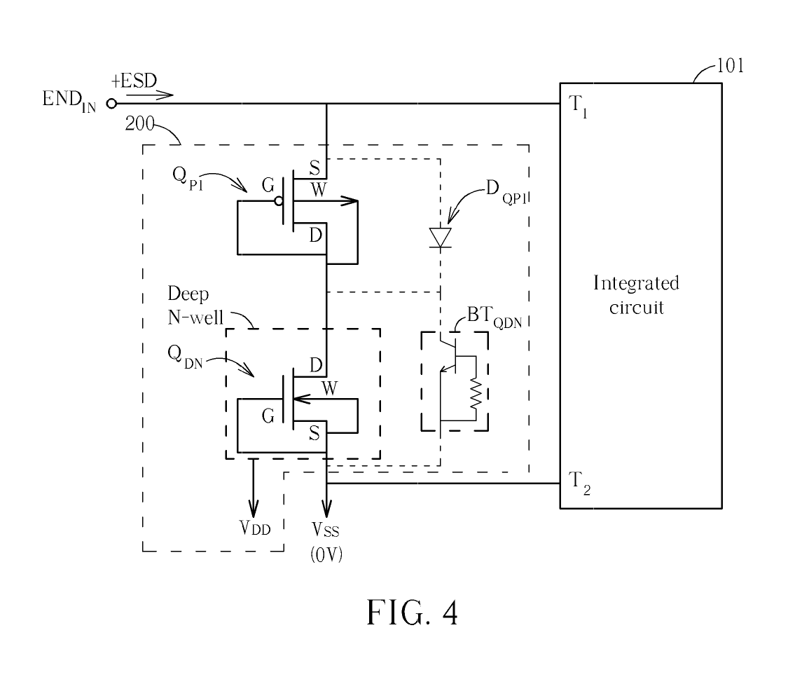

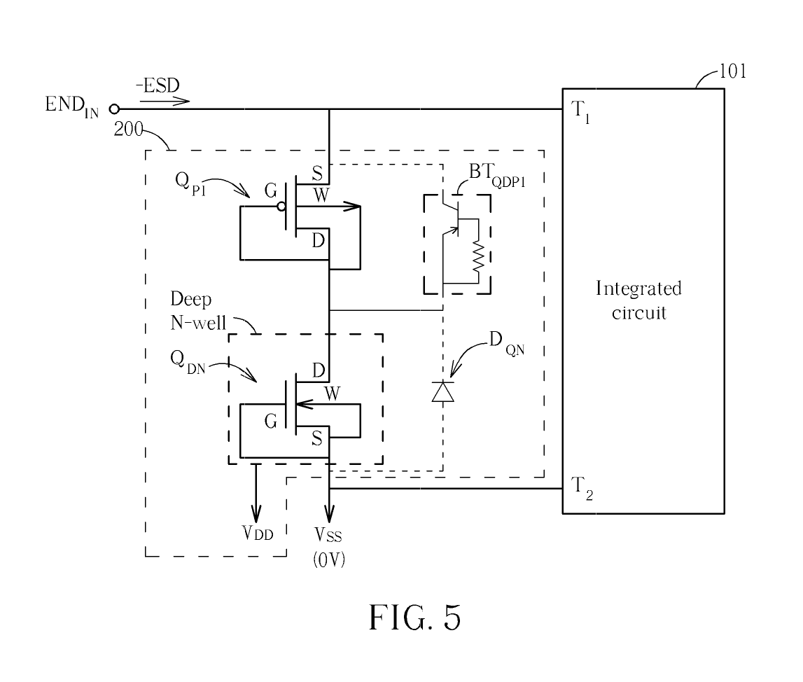

Please refer to FIG. 4 and FIG. 5. FIG. 4 and FIG. 5 are diagrams illustrating the operation principle of the ESD protection circuit 200 dissipating the static electricity. In FIG. 4, assume the positive static electricity +ESD is generated from the input end END_{IN}, since the positive static electricity +ESD is at a very high voltage level, the parasitic bipolar transistor BT_{QDN} of the deep N-well NMOS transistor Q_{DN} is turned on. In this way, the positive static electricity +ESD flows to the voltage source V_{SS} through the turned-on parasitic diode D_{QP1} of the PMOS transistor D_{QP1} and the turned-on parasitic bipolar transistor BT_{QDN} of the deep N-well NMOS transistor Q_{DN}, so that the ESD protection circuit 200 can dissipate the positive static electricity +ESD. Similarly, in FIG. 5, assume the negative static electricity −ESD is generated from the input end END_{IN}, since the negative static electricity −ESD is at a very high voltage level, the parasitic bipolar transistor BT_{QDP1} of the PMOS transistor Q_{P1} is turned on. In this way, the positive charges from the voltage source V_{SS} flow through the turned-on parasitic bipolar transistor BT_{QDP1} of the PMOS transistor D_{QP1} and the turned-on D_{QN} of the deep N-well NMOS transistor Q_{DN} to eliminate the negative static electricity −ESD, so that the ESD protection circuit 200 can dissipate the negative static electricity −ESD.

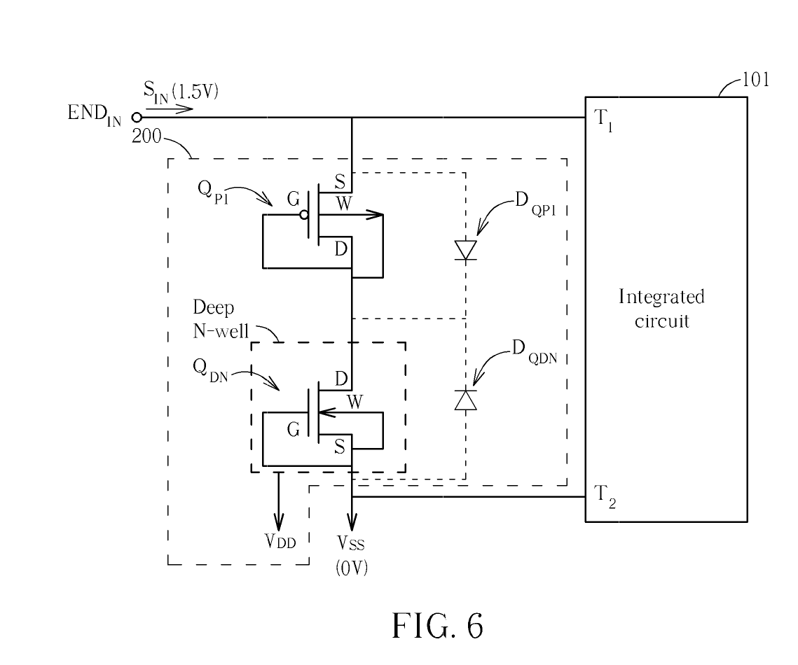

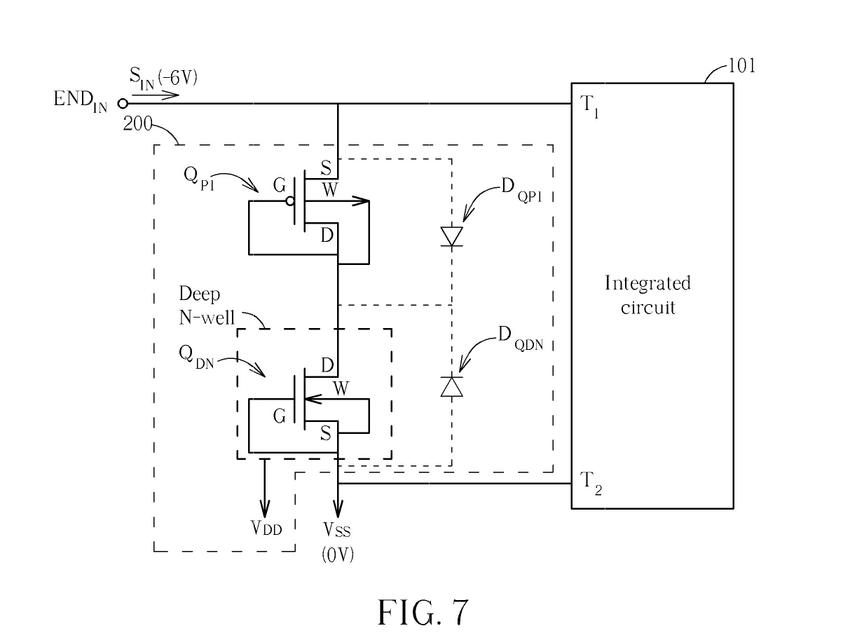

Please refer to FIG. 6 and FIG. 7. FIG. 6 and FIG. 7 are diagrams illustrating that the ESD protection circuit 200 increasing the operation voltage range of the input signal S_{IN} of the integrated circuit 101. In FIG. 6, it is assumed that the input signal S_{IN} is at 1.5V. Meanwhile, the parasitic diode D_{QP1} of the PMOS transistor Q_{P1} is turned on. However, since the parasitic diode D_{QDN} of the deep N-well NMOS transistor Q_{DN} is reversely connected to the parasitic diode D_{QP1}, the parasitic diode D_{QDN} is turned off. As a result, the input signal S_{IN} is inputted into the integrated circuit 101 through the terminal T₁, and is not affected by the ESD protection circuit 200. In FIG. 7, it is assumed that the input signal S_{IN} is at −6V. Meanwhile, the parasitic diode D_{QDN} is turned on. However, since the parasitic diode D_{QP1} is reversely connected to the parasitic diode D_{QDN}, the parasitic diode D_{QP1} is turned off. Hence, the input signal S_{IN} is inputted into the integrated circuit 101 through the terminal T₁, and is not affected by the ESD protection circuit 200. Consequently, no matter the voltage level of the input signal S_{IN} is higher or lower than the voltage source V_{SS}, the input signal S_{IN} is inputted into the integrated circuit 101 through the terminal T₁, and is not affected by the ESD protection circuit 200. In other words, compared with the conventional ESD protection circuit 100, the ESD protection circuit 200 increases the operation voltage range of the input signal S_{IN}. In addition, the leakage current between the terminals T₁ and T₂ is avoided as well.

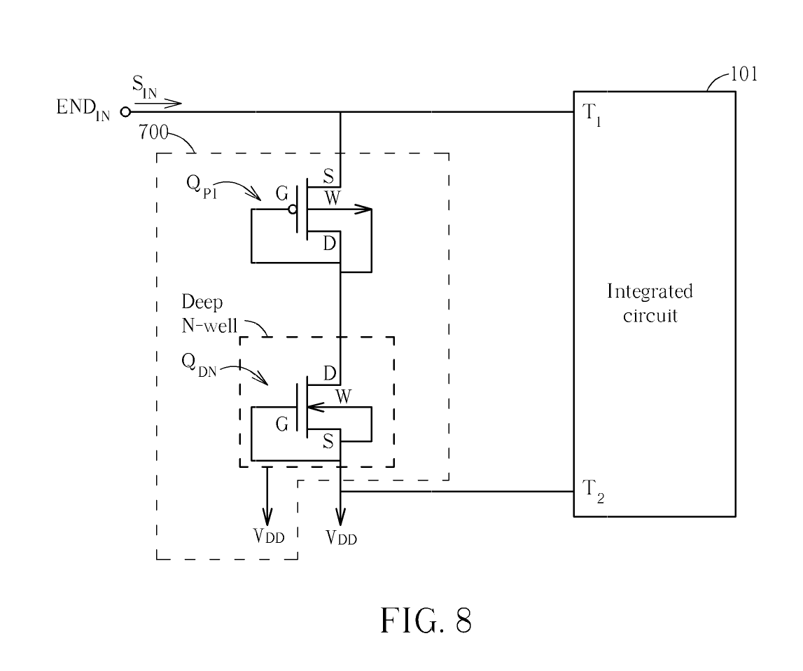

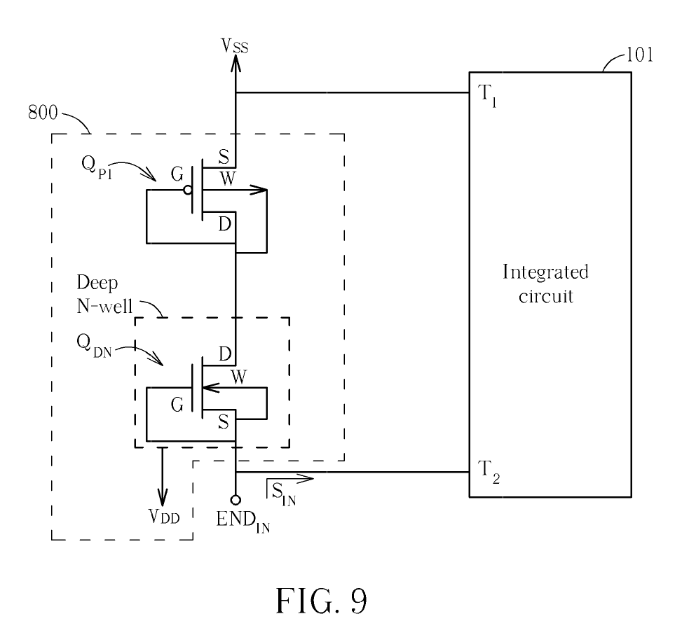

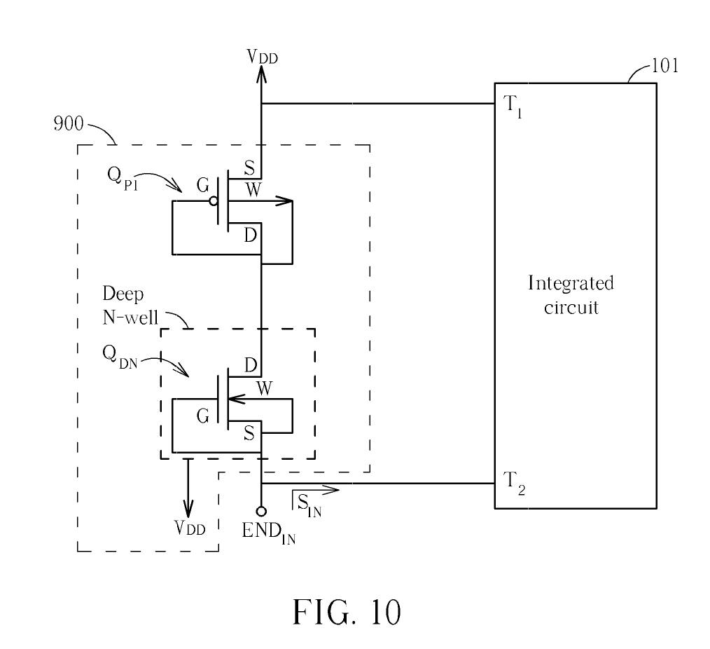

Please refer to FIG. 8, FIG. 9, and FIG. 10. FIG. 8 is an ESD protection circuit 700 according to a second embodiment of the present invention. Compared with FIG. 2, in FIG. 8, the terminal T₂ is coupled to a voltage source V_{DD}, which provides a high-level voltage. FIG. 9 is an ESD protection circuit 800 according to a third embodiment of the present invention. Compared with FIG. 2, in FIG. 9, the terminal T₂ is utilized for the integrated circuit 101 to receive the input signal S_{IN}, and the terminal T₁ is coupled to a voltage source V_{SS}. FIG. 10 is an ESD protection circuit 900 according to a fourth embodiment of the present invention. Compared with FIG. 2, in FIG. 10, the terminal T₂ is utilized for the integrated circuit 101 to receive the input signal S_{IN}, and the terminal T₁ is coupled to a voltage source V_{DD}. The structure and the operation principle of the ESD protection circuits 700, 800, and 900 are similar to those of the ESD protection circuit 200, and will not be repeated again for brevity. The ESD protection circuits 700, 800, and 900 can increase the operation voltage range of the input signal S_{IN} and avoid the leakage current between the terminals T₁ and T₂ as well.

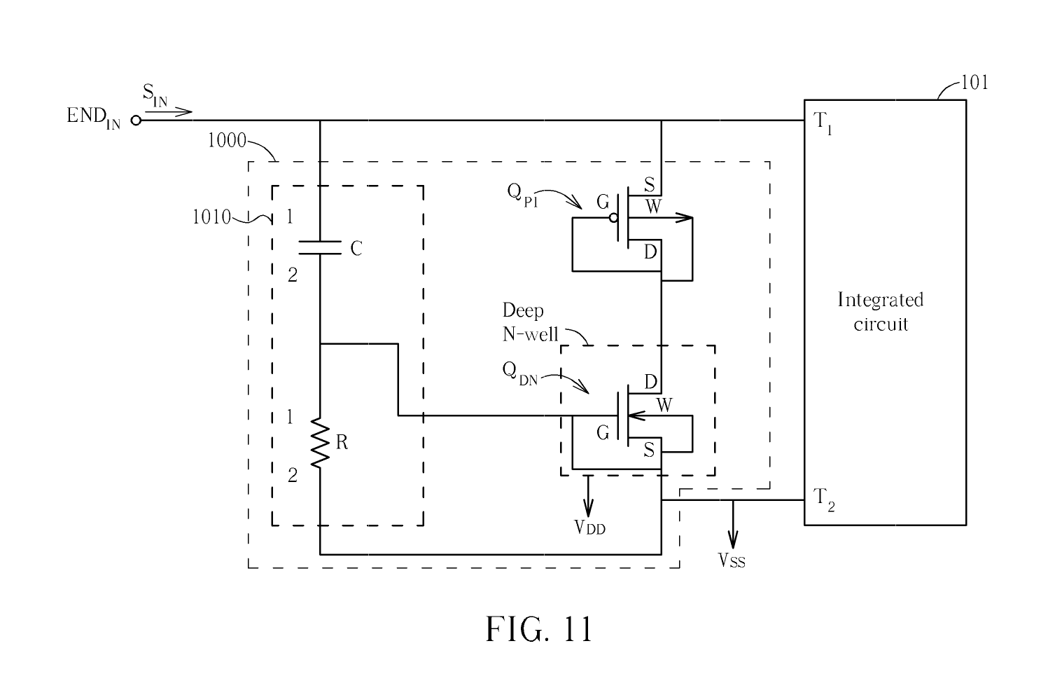

Please refer to FIG. 11. FIG. 11 is a diagram illustrating an ESD protection circuit 1000 according to a fifth embodiment of the present invention. Compared with the ESD protection circuit 200, the ESD protection circuit 1000 further includes a driving circuit 1010 coupled to the gate of the deep N-well NMOS transistor Q_{DN}. The driving circuit 1010 includes a capacitor C and a resistor R. The first end of the capacitor C is coupled to the terminal T₁. The second end of the capacitor C is coupled to the gate of the deep N-well NMOS transistor Q_{DN}. The first end of the resistor R is coupled to the gate of the deep N-well NMOS transistor Q_{DN}. The second end of the resistor R is coupled to the terminal T₂. When the positive static electricity +ESD is generated from the input end END_{IN}, since the static electricity has a high frequency, the gate of the deep N-well NMOS transistor Q_{DN} receives a high-level voltage through the capacitor C. In this way, the deep N-well NMOS transistor Q_{DN} is turned on, so that the deep N-well NMOS transistor can accelerate the speed of the positive static electricity +ESD flowing to the voltage source V_{SS}. Therefore, compared with the ESD protection circuit 200, the ESD protection circuit 1000 can dissipate the positive static electricity +ESD more rapidly.

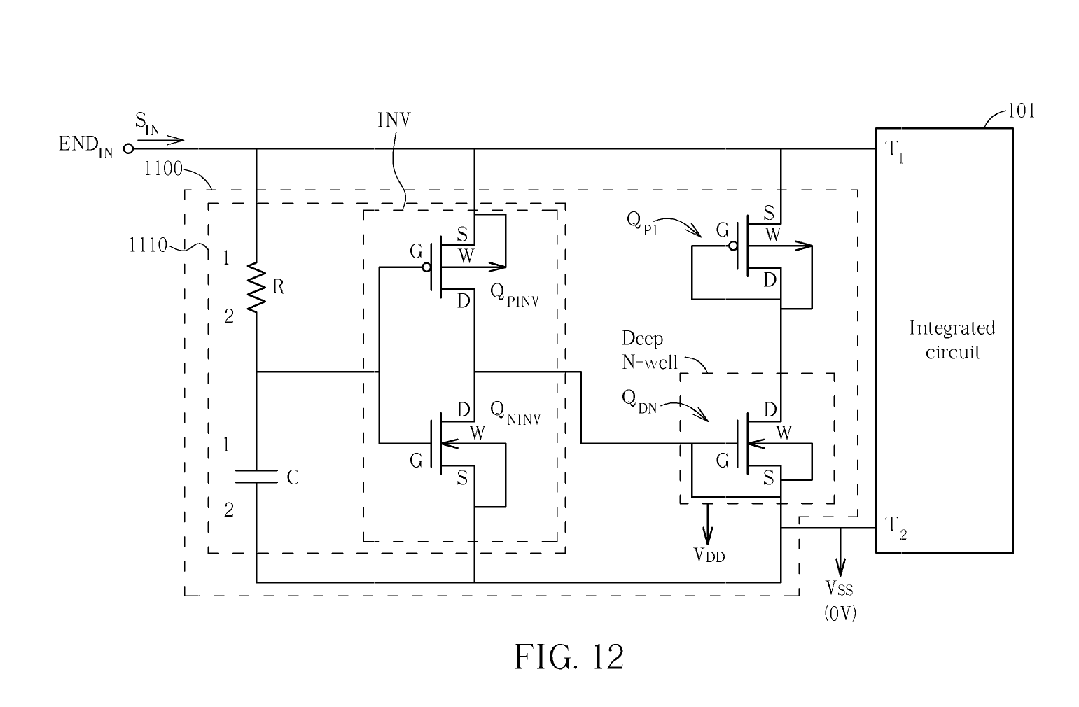

Please refer to FIG. 12. FIG. 12 is an ESD protection circuit 1100 according to a sixth embodiment of the present invention. Compared with the ESD protection circuit 200, the ESD protection circuit 1100 further includes a driving circuit 1110 coupled to the gate of the deep N-well NMOS transistor Q_{DN}. The driving circuit 1110 includes an inverter INV, a capacitor C, and resistor R. The inverter INV includes a PMOS transistor Q_{PINV}, and an NMOS transistor Q_{NINV}. The well of the PMOS transistor Q_{PINV} is coupled to the source of the PMOS transistor Q_{PINV}, and the source of the PMOS transistor Q_{PINV} is coupled to the terminal T₁. The drain of the PMOS transistor Q_{PINV} is coupled to the gate of the deep N-well NMOS transistor Q_{DN}. The well of the NMOS transistor Q_{NINV} is coupled to the source of the NMOS transistor Q_{NINV}, and the source of the NMOS transistor Q_{NINV} is coupled to the terminal T₂. The drain of the NMOS transistor Q_{NINV} is coupled to the gate of the deep N-well NMOS transistor Q_{DN}. The first end of the resistor R is coupled to the terminal T₁ and the second end of the resistor R is coupled to the gates of the PMOS transistor Q_{PINV} and the NMOS transistor Q_{NINV}. The first end of the capacitor C is coupled to the gates of the PMOS transistor Q_{PINV} and the NMOS transistor Q_{NINV}, and the second end of the capacitor C is coupled to terminal T₂. When the positive static electricity +ESD is generated from the input end END_{IN}, since the static electricity has a high frequency, the capacitor C is treated as a short circuit. Therefore, the gates of the PMOS transistor Q_{PINV} and the NMOS transistor Q_{NINV} receive the voltage V_{SS} (0V) through the capacitor C, so that the PMOS transistor Q_{PINV} is turned on and the NMOS transistor Q_{NINV} is turned off. In this way, the inverter INV outputs a high-level voltage, so that the deep N-well NMOS transistor Q_{DN} is turned on. Similarly, the deep N-well NMOS transistor accelerates the speed of the positive static electricity +ESD flowing to the voltage source V_{SS}. That is, compared with the ESD protection circuit 200, the ESD protection circuit 1100 dissipates the positive static electricity +ESD more rapidly.

In conclusion, the ESD protection circuit provided by the embodiments of the present invention is coupled between a first terminal and a second terminal of an integrated circuit for preventing the integrated circuit from being damaged by static electricity. One of the first terminal and the second terminal is utilized for inputting a voltage into the integrated circuit, and the other one of the first terminal and the second terminal is coupled to a voltage source. The ESD protection circuit includes a PMOS transistor and a deep N-well NMOS transistor. The static electricity is dissipated by means of the parasitic diodes and the parasitic bipolar transistors of the PMOS transistor and the deep N-well NMOS transistor, and the leakage current between the first terminal and the second terminal is avoided by means of the parasitic diode of the PMOS transistor reversely connected to the parasitic diode of the deep N-well NMOS transistor. In this way, the ESD protection circuit prevents the integrated from being damaged by the static electricity and increases the operation voltage range of the signal inputted into the integrated circuit.

Those skilled in the art will readily observe that numerous modifications and alterations of the device and method may be made while retaining the teachings of the invention.

What is claimed is:

1. An electrostatic discharge (ESD) protection circuit, coupled between a first terminal and a second terminal of an integrated circuit for preventing the integrated circuit from being damaged by static electricity, the ESD protection circuit comprising:
a first P-channel Metal Oxide Semiconductor (PMOS) transistor, comprising:
a source;
a source coupled to the first terminal;
a gate coupled to the drain of the first PMOS transistor; and
an N-well coupled to the drain of the first PMOS transistor; and
a deep N-well N-channel Metal Oxide Semiconductor (NMOS) transistor, comprising:
a source coupled to the second terminal;
a drain coupled to the drain of the first PMOS transistor;
a gate coupled to the second terminal;
a P-well coupled to the source of the deep N-well NMOS transistor; and
a deep N-well utilized for covering the P-well, coupled to a second voltage source.

2. The ESD protection circuit of claim 1, wherein the second voltage source is a high-level voltage.

3. The ESD protection circuit of claim 1, wherein the first terminal is utilized for the integrated circuit to receive an input signal and the second terminal is coupled to a first voltage source.

4. The ESD protection circuit of claim 1, wherein the second terminal is utilized for the integrated circuit to receive an input signal and the first terminal is coupled to a first voltage source.

5. The ESD protection circuit of claim 1, further comprising:
a driving circuit coupled to the gate of the deep N-well NMOS transistor.

6. The ESD protection circuit of claim 5, wherein the driving circuit comprises:
a capacitor comprising a first end coupled to the first terminal, and a second end coupled to the gate of the deep N-well NMOS transistor; and
a resistor comprising a first end coupled to the gate of the deep N-well NMOS transistor, and a second end coupled to the second terminal.

7. The ESD protection circuit of claim 5, wherein the driving circuit comprises:
an inverter comprising:
a second PMOS transistor, comprising:
a drain;
a source coupled to the first terminal;
a gate; and
an N-well coupled to the source of the second PMOS transistor; and
a first NMOS transistor, comprising:
a source coupled to the second terminal;
a drain coupled to the drain of the second PMOS transistor;
a gate coupled to the gate of the second PMOS transistor; and
a P-well coupled to the source of the first NMOS transistor;
a resistor comprising:
a first end coupled to the first terminal; and
a second end coupled to the gate of the second PMOS transistor and the gate of the first NMOS transistor; and
a capacitor comprising:
a first end coupled to the second end of the resistor; and
a second end coupled to the second terminal.
